(19) United States
(12) Patent Application Publication
(10) Pub. No.: US 2017/0278754 A1
(43) Pub. Date: Sep. 28, 2017

(54) METHOD FOR PRODUCING GROUP III NITRIDE CRYSTAL, AND RAMO4 SUBSTRATE

(71) Applicant: Panasonic Intellectual Property Management Co., Ltd., Osaka (JP)

(72) Inventors: ISAO TASHIRO, Osaka (JP); HIDENAO KATAOKA, Osaka (JP); YOSHIO OKAYAMA, Osaka (JP); NOBUYUKI YOKOYAMA, Osaka (JP); YOSHIFUMI TAKASU, Osaka (JP)

(21) Appl. No.: 15/428,627

(22) Filed: Feb. 9, 2017

(30) Foreign Application Priority Data
Mar. 25, 2016 (JP) 2016-061043
Oct. 27, 2016 (JP) 2016-210878

(51) Int. Cl. H01L 21/78; C30B 33/00; H01L 33/00; C01F 17/00; H01L 21/02; C30B 25/18; C30B 29/40

(52) U.S. Cl. CPC H01L 21/7813; C30B 25/18; C30B 33/00; C30B 29/403; C01F 17/0025; H01L 21/0242; H01L 21/02428; H01L 21/0254; H01L 33/007; H01L 33/0079

(57) ABSTRACT

A method for producing a Group III nitride crystal, includes: preparing an RAMO₄ substrate containing a single crystal represented by the general formula RAMO₄ (wherein R represents one or a plurality of trivalent elements selected from a group consisting of Sc, In, Y, and a lanthanoid element, A represents one or a plurality of trivalent elements selected from a group consisting of Fe(III), Ga, and Al, and M represents one or a plurality of divalent elements selected from a group consisting of Mg, Mn, Fe(II), Co, Cu, Zn, and Cd) and having a notch on a side portion thereof; growing a Group III nitride crystal on the RAMO₄ substrate; and cleaving the RAMO₄ substrate from the notch.

### TECHNICAL FIELD

The technical field relates to a method for producing a Group III nitride crystal, and an RAMO₄ substrate.

### BACKGROUND

An ScAlMgO₄ substrate has been known as a substrate represented by the general formula RAMO₄ (wherein R represents one or a plurality of trivalent element selected from the group consisting of Sc, In, Y, and a lanthanoid element, A represents one or a plurality of trivalent element selected from the group consisting of Fe(III), Ga, and Al, and M represents one or plurality of divalent elements selected from the group consisting of Mg, Mn, Fe(II), Co, Cu, Zn, and Cd). The ScAlMgO₄ substrate is used as a growth substrate for a nitride semiconductor, such as GaN (see, for example, Patent Literature 1). FIG. 11 is a diagram showing the process steps of the method for producing an ScAlMgO₄ substrate described in Patent Literature 1. In the step S201 for forming a single crystal, a bulk material of ScAlMgO₄ is formed. In the step S202 for producing a growth substrate, the bulk material is cleaved to form a substrate. In the step S203 for forming GaN, a GaN layer is formed on the substrate. In the step S204 for removing the growth substrate, the ScAlMgO₄ substrate as the growth substrate is removed by etching with a buffered hydrofluoric acid or the like, or the growth substrate is removed by cleaving a part of the ScAlMgO₄ substrate, and then further by etching or polishing. A GaN substrate is finally obtained by performing these process steps. Patent Literature 1: JP-A-2015-178448

### SUMMARY

In Patent Literature 1 as described above, in the production of a GaN substrate, the RAMO₄ substrate is removed by etching or polishing in the step S204. In the case where a part of the RAMO₄ substrate is removed by cleaving, the RAMO₄ substrate thus removed is once dissolved and then reused by forming again into a single crystal. However, in consideration of the cost, the production efficiency and the like of the production of a GaN substrate in recent years, there is a demand of easy reuse of the removed RAMO₄ substrate.

An object herein is to provide a method for enhancing the use efficiency of a RAMO₄ substrate in the production of a Group III nitride.

For achieving the aforementioned and other objects, there is provided, as one aspect, a method for producing a Group III nitride crystal, containing: preparing an RAMO₄ substrate containing a single crystal represented by the general formula RAMO₄ (wherein R represents one or a plurality of trivalent elements selected from the group consisting of Sc, In, Y, and a lanthanoid element, A represents one or a plurality of trivalent elements selected from the group consisting of Fe (III) , Ga, and Al, and M represents one or a plurality of divalent elements selected from the group consisting of Mg, Mn, Fe(II), Co, Cu, Zn, and Cd) having a notch on a side portion thereof; growing a Group III nitride crystal on the RAMO₄ substrate; and cleaving the RAMO₄ substrate from the notch as an origin.

There is also provided, as another aspect, a RAMO₄ substrate containing a single crystal represented by the general formula RAMO₄ (wherein R represents one or a plurality of trivalent elements selected from the group consisting of Sc, In, Y, and a lanthanoid element, A represents one or a plurality of trivalent elements selected from the group consisting of Fe(III), Ga, and Al, and M represents one or a plurality of divalent elements selected from the group consisting of Mg, Mn, Fe(II), Co, Cu, Zn, and Cd), the RAMO₄ substrate having a notch on a side portion thereof.

According to the aforementioned and other aspects, the method produces a Group III nitride and a RAMO₄ substrate that is capable of easy reuse.

### BRIEF DESCRIPTION OF THE DRAWINGS

FIG. 1 is a diagram showing the production process of a Group III nitride substrate in the embodiment 1.

FIG. 2 is a figure for explaining: (a) is a perspective view showing the shape of the ScAlMgO₄ ingot after the outline machining in the embodiment 1; (b) and (c) each are a side view showing the shape of the notch of the ScAlMgO₄ ingot in the embodiment 1; and (d) is a top plan view showing the ScAlMgO₄ ingot in the embodiment 1.

FIGS. 3A and 3B each are a schematic illustration showing the shape of the blade used for cleaving in the embodiment 1.

FIG. 4 is a graph showing the measurement result of the flatness of the epitaxial growth surface formed only by cleaving.

FIG. 5 is a figure for explaining: (a) is a plan view and a side view showing the ScAlMgO₄ substrate having a notch after cleaving in the embodiment 1; (b) is a side view showing the ScAlMgO₄ substrate having a GaN layer formed thereon in the embodiment 1; (c) is a side view showing the state where the ScAlMgO₄ substrate is removed in the embodiment 1; and (d) is a side view showing the GaN substrate formed in the embodiment 1.

FIG. 6 is a graph showing the measurement result of the flatness after performing the coarse irregularity forming step in the embodiment 1.

FIG. 7 is a graph showing the measurement result of the flatness after performing the minute irregularity forming step in the embodiment 1.

FIG. 8 is an illustration showing the measurement result of an AFM after performing the minute irregularity forming step in the embodiment 1.

FIG. 9 is a diagram showing the production process of a Group III nitride substrate according to embodiment 2.

FIG. 10 is a figure for explaining: (a) is a side view showing the ScAlMgO₄ substrate having a GaN layer formed according to embodiment 2; and (b) is a side view showing the substrate having a device formed thereon in the embodiment 2.

FIG. 11 is a diagram showing the production process of an ScAlMgO₄ substrate.

### DESCRIPTION OF EMBODIMENTS

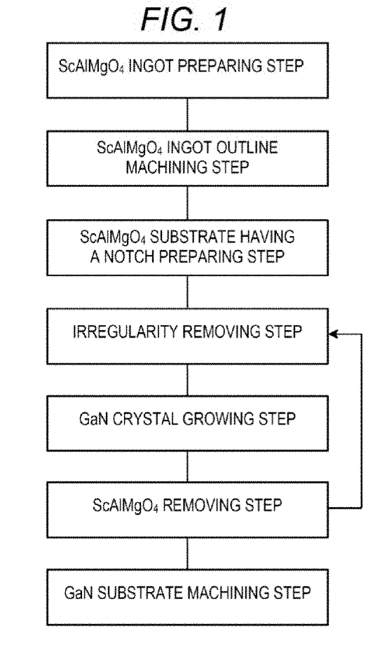

An embodiment will be described with reference to FIGS. 1 to 10. The embodiment will be described with reference to GaN for the Group III nitride and ScAlMgO₄ for the RAMO₄ substrate.

### EMBODIMENT 1

FIGS. 5 (a) to 5 (d) show process steps of a method for producing a Group III nitride according to the embodiment 1. The method for producing a Group III nitride crystal includes a step of preparing an ScAlMgO₄ substrate 10 formed of an ScAlMgO₄ single crystal having a notch 2b on the side portion thereof (FIG. 5(a)), a step of growing a Group III nitride crystal 4 on the ScAlMgO₄ substrate 10 (FIG. 5 (b)) , and a step of cleaving the ScAlMgO₄ substrate 10 from the notch 2b as an origin (FIG. 5(c)).

The upper figure of FIG. 5(a) is a plan view of the principal surface of the ScAlMgO₄ substrate 10, and the lower figure thereof is a side view in the thickness direction of the ScAlMgO₄ substrate 10, and particularly is an enlarged view of a part of the side portion of the ScAlMgO₄ substrate 10. The principal surface of the ScAlMgO₄ substrate 10 is a cleaved surface of the ScAlMgO₄ single crystal, and the notch 2b is disposed on the side portion of the ScAlMgO₄ substrate 10 in substantially parallel to the cleavage surface. In the step of FIG. 5(b), a Group III nitride crystal is grown with the ScAlMgO₄ substrate 10 as a seed substrate on the principal surface thereof. Thereafter, the ScAlMgO₄ substrate 10 is easily divided from the notch 2b as an origin into a side 10b having the Group III nitride crystal formed thereon and a side 10a having no Group III nitride crystal formed. Accordingly, the side 10a having no Group III nitride crystal formed can be reused. For example, the side 10a having no Group III nitride crystal formed can be reused, and a Group III nitride crystal may be grown on the principal surface thereof.

A method for producing a Group III nitride crystal including a method for producing the ScAlMgO₄ substrate 10 will be described in more detail. The method will be described with reference to GaN (gallium nitride) for the Group III nitride.

As shown in FIG. 1, the method in detail contains: an ScAlMgO₄ ingot preparing step of forming a single crystal ScAlMgO₄; an ScAlMgO₄ ingot outline machining step of machining the single crystal ScAlMgO₄ ingot to prepare a cylindrical ScAlMgO₄ ingot 1 having plural notches 2a and 2b on the side portion thereof; an ScAlMgO₄ substrate preparing step of machining the ingot 1 into the form of a substrate to prepare an ScAlMgO₄ substrate 10 having the notch 2b on the side portion thereof; an irregularity removing step of removing irregularities on a surface (principal surface) corresponding to an epitaxial growth surface of the ScAlMgO₄ substrate 10; a GaN crystal growing step of growing a GaN layer 4 on the principal surface of the ScAlMgO₄ substrate 10; an ScAlMgO₄ removing step of removing the ScAlMgO₄ substrate from the notch 2b as an origin; and a GaN substrate machining step of forming the principal surface of the GaN substrate 4a into an epi-ready surface. The steps will be described in detail below.

In the ScAlMgO₄ ingot preparing step, a single crystal ScAlMgO₄ ingot produced, for example, with a high-frequency induction heating type Czochralski furnace is prepared. As an example of the production method of the ingot, a method for producing an ingot having a diameter of 50 mm will be described. As a starting material, Sc₂O₃, Al₂O₃, and MgO each having a purity of 4N (99.99%) are mixed in the prescribed molar ratio. 3,400 g of the starting material is placed in a crucible formed of iridium having a diameter of 100 mm. The crucible having the starting material placed therein is then placed in a high-frequency induction heating type Czochralski furnace (growing furnace), and the interior of the furnace is vacuumed. Thereafter, nitrogen is introduced into the furnace, and at the time when the interior of the furnace is at atmospheric pressure, the crucible is heated. The starting material is melted by gradually heating the material over 12 hours to the melting point of ScAlMgO₄. An ScAlMgO₄ single crystal having been cut into the (0001) azimuth is used as a seed crystal, and the seed crystal is descended to the vicinity of the molten liquid in the crucible. Thereafter, while rotating the seed crystal, the seed crystal is gradually descended to make the tip end of the seed crystal contact the molten liquid. Then, the seed crystal is raised at a raising speed of 0.5 mm/h (i.e., withdrawing in the (0001) azimuthal direction) while gradually decreasing the temperature to grow a crystal. According to the procedure, a single crystal ingot having a diameter of 50 mm and a length of the straight body portion of 50 mm is obtained.

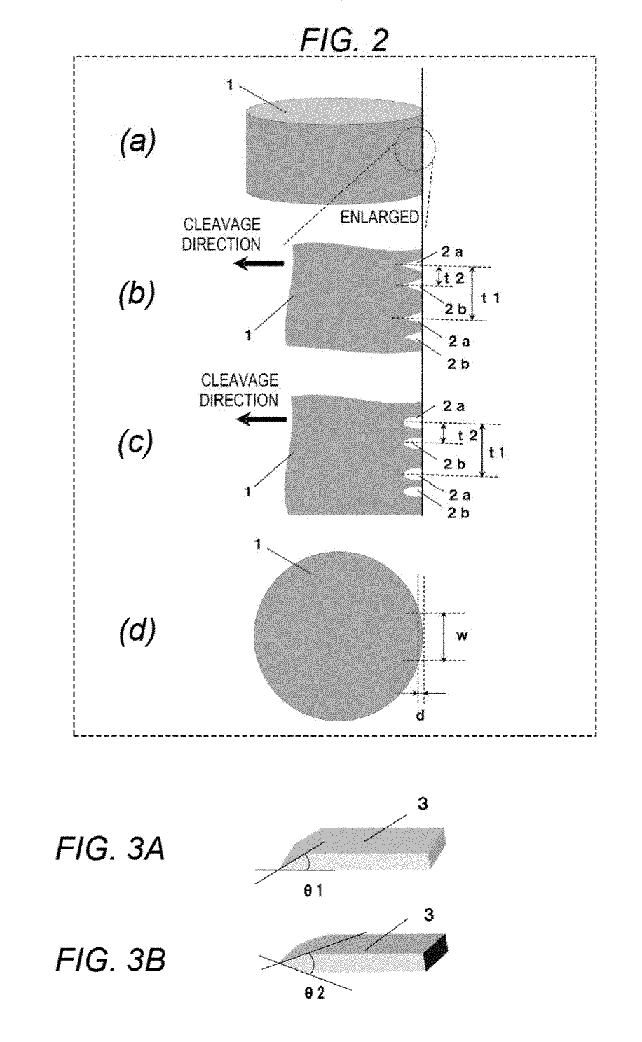

In the ScAlMgO₄ ingot outline machining step, the ingot thus withdrawn is machined into a cylinder shape, and a notch is formed on the side portion of the cylinder. The both ends (i.e., the top and the tail) of the ingot are cut out with a band saw, a slicer having an inner blade or an outer blade, a single wire saw, or the like. The ScAlMgO₄ ingot withdrawn does not have a regular circular shape, and thus formed into a cylinder by outline grinding with a diamond wheel or the like or by polishing with a polishing cloth. FIG. 2 (a) is a perspective view showing the ScAlMgO₄ ingot 1 in a cylinder shape.

The ScAlMgO₄ single crystal will be described. The ScAlMgO₄ single crystal has a structure containing an ScO₂ layer like the (111) plane of the rock salt structure and an AlMgO₂ layer like the (0001) plane of the hexagonal structure, which are laminated alternately. The two layers like the (0001) plane of the hexagonal structure are of a planar structure as compared to the wurtzite structure, and the bond between the upper and lower layers is longer than the bond in the plane by approximately 0.03 nm, and has a weak bond strength. Accordingly, the ScAlMgO₄ single crystal can be cleaved at the (0001) plane. By utilizing the characteristics, in the ScAlMgO₄ substrate preparing step, the ScAlMgO₄ ingot 1 having a cylinder shape is formed into a substrate having a prescribed thickness. At this time, an origin for cleavage is necessary, and notches 2a and 2b are formed on the side portion in the ScAlMgO₄ ingot outline machining step. The method for forming the origin will be described with reference to FIGS. 2(b) and 2(c).

As shown in FIGS. 2(b) and 2(c), in the case where the thickness of the final ScAlMgO₄ substrate is t1 in the ScAlMgO₄ substrate preparing step, notches 2a are formed as origins with a pitch t1. Furthermore, for forming a substrate having a notch 2b, notches each are formed at a position that is remote from the origin with the pitch t1 in the same direction as the pitch by a distance t2. The notch 2a is an origin of cleavage at the time when the substrate is produced from the ingot, and the notch 2b is an origin of cleavage at the time when the ScAlMgO₄ substrate is reused. For example, the notches are formed with t1=500 μm and t2=100 μm.

The method for forming the notch will be described. FIG. 2 (b) shows the shape of the notch formed by dicing or laser machining. In the case of the dicing, the machining is performed, for example, with a blade having a diameter of 100 mm, an abrasive grain diameter of 30 μm, and a grain size of #600 rotated at a rotation number of 1,800 min ⁻¹. In the case of the laser machining, for example, with a YAG laser having a pulse width in a nanosecond order, a laser having a wavelength of 400 nm or less and a pulse width of 100 nsec or less may be used. With an ultra short pulse laser having a pulse width of 1 nsec or less, an infrared laser and a visible light laser may be used. The notch thus formed by dicing or laser machining has a shape with an incisive end in a macroscopic view as shown in FIG. 2 (b). FIG. 2 (c) shows the shape of the notch formed by machining with a wire saw. In the case where the notches are formed one by one with a wire saw, a single wire saw may be used, and the plural notches are machined simultaneously, a multiple wire saw may be used. With a smaller wire diameter of the wire saw used, a notch having a shape with a smaller width can be formed. The wire saw used may be, for example, a fixed abrasive grain wire saw having a core diameter of 80 μm with diamond abrasive grains having a size of from 8 to 16 μm electrodeposited thereon. In the case where the notches are formed with a multiple wire saw, the plural notches 2a are formed at the pitch t1, and then the plural notches 2b are formed after shifting the ingot or the wire by the distance t2. The notch thus formed with a wire saw has a shape with a rounded end in a macroscopic view as shown in FIG. 2(c).

FIG. 2 (d) is a top plan view showing the ScAlMgO₄ ingot 1 viewed from the circular surface (top surface). The notch shown in FIG. 2 (d) preferably has a depth d of 0.1 mm or more and 5 mm or less and a width w in the circumferential direction of 0.1 mm or more and 15 mm or less. For example, in the case where the ScAlMgO₄ ingot 1 is a 2-inch cylinder (diameter: 50 mm), when the depth d of the notch is 0.1 mm, the width w in the circumferential direction is geometrically determined and is 4.46 mm. In the case where the ScAlMgO₄ ingot 1 is a 4-inch cylinder (diameter: 100 mm), when the depth d of the notch is 0.1 mm, the width w in the circumferential direction is geometrically determined and is 6.32 mm. In the case where the ScAlMgO₄ ingot 1 is not a cylinder, the depth d and the width w of the notch each are determined depending on the shape. When the depth d of the notch is too large, the effective area of the substrate may be decreased, and thus the depth d may be determined within the range that provides the allowable effective area of the substrate. The range that provides the allowable effective area of the substrate (the depth d of the notch) is specifically 5 mm or less. In the case of a cylinder shape, the width is geometrically determined when the depth is fixed. Accordingly, the width w may be 15 mm or less.

In the case where the ScAlMgO₄ ingot 1 is actually cleaved, the blade 3 having the shape shown in FIG. 3A or 3B is attached to the notch 2a or 2b for cleaving. Accordingly, the shape of the notch is preferably such a shape that the blade edge can sharply cut into the notch, and as shown in FIG. 2(b), the notch preferably has a shape with an incisive end (i.e., the end on the side of the interior of the ingot 1).

It may be considered to provide plural notches 2b on the same plane, but when the ingot is cleaved from plural positions without sufficient positioning, steps may be formed on the cleaved surface. Accordingly, in the case where plural notches are provided on the same plane, it is necessary to perform atomic level positioning, which is practically difficult, and therefore it suffices that only one notch may be provided on the same plane.

The ScAlMgO₄ substrate preparing step will be described. In this step, for providing an ScAlMgO₄ substrate 10 having a notch, the blade 3 shown in FIG. 3A or 3B is attached to the notch 2a, and a force is applied thereto in the cleavage direction to cleave the ingot, thereby providing the ScAlMgO₄ substrate 10 having the thickness t1 from the ingot 1 in the form of a cylinder. The blade 3 may be formed of a steel. Representative examples of the shape of the blade 3 are shown in FIGS. 3A and 3B. The blade 3 may be a single edged blade as shown in FIG. 3A, or may be a double edged blade as shown in FIG. 3B. The angle of the blade 3 (which is the angle shown by θ1 in FIG. 3A or θ2 in FIG. 3B) is preferably 30° or less. The shape of the blade 3 is not limited to the shapes shown in FIGS. 3A and 3B, and for example, in the case of a double edged blade, the angle shown by θ2 may be asymmetric with respect to the center of the blade edge, and the angle may be changed stepwise in multiple steps.

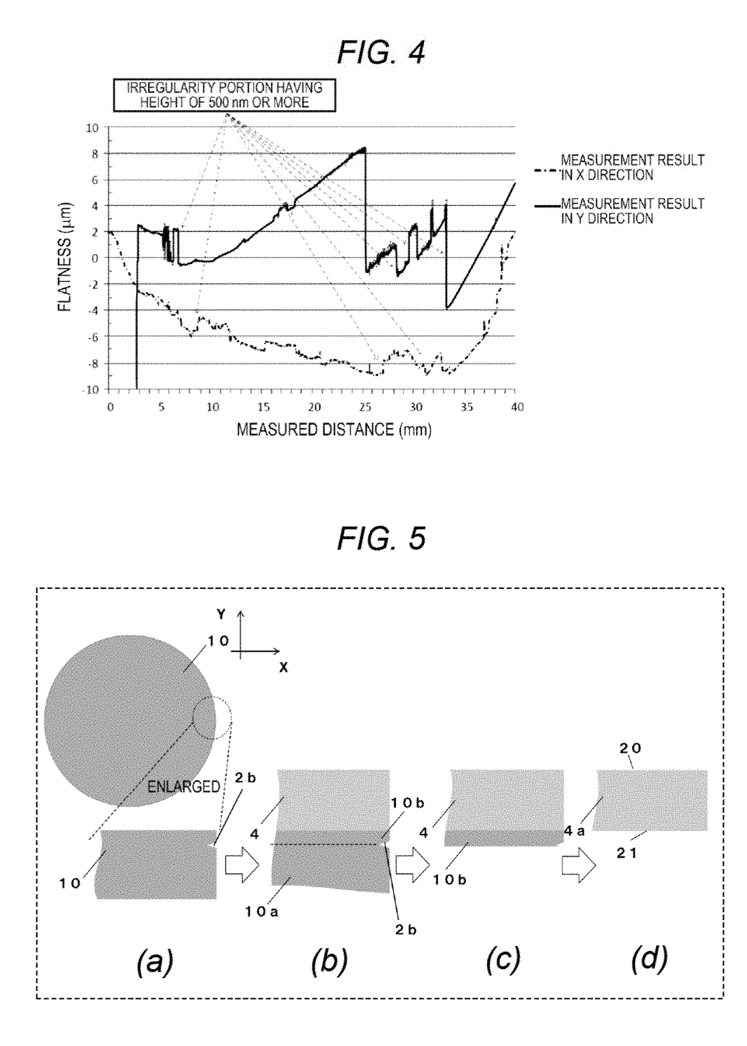

FIG. 4 shows the measurement data of the flatness of the cleaved surface (i.e., the epitaxial growth surface of the ScAlMgO₄ substrate) after cleaving an ScAlMgO₄ bulk material. The data are obtained with a laser reflection length measurement equipment (NH-3MA, produced by Mitaka Kohki Co., Ltd.) in the XY axes perpendicular to each other in one plane of the ScAlMgO₄ substrate having a diameter of 40 mm. In FIG. 4, the cleaved surface obtained by cleaving the bulk material has irregularity portions having steps of 500 nm or more as shown by the arrows. In the ScAlMgO₄ substrate, it is considered that due to the fluctuation of the cleaving force in the cleavage direction on cleaving, the cleavage does not occur in the same atomic layer, but irregularity portions having steps of 500 nm or more are consequently formed. The presence of the steps having a height of 500 nm or more may cause a problem in epitaxial growth of a crystal on the substrate. The problem occurring in the case where steps having a height of 500 nm or more are present on the epitaxial growth surface of the substrate will be described. In the case where a crystal, such as GaN, is formed on an epitaxial growth surface having steps having a height of 500 nm or more, the crystal orientation at the step having a height of 500 nm is differentiated. For example, when an InGaN layer used as an LED light emitting layer is formed by an MOCVD (metal-organic chemical vapor deposition) method on an epitaxial growth surface, the composition of indium is differentiated between the step portion and the flat portion. The difference of the composition of indium changes the light emission wavelength and the luminance of the LED device. Consequently, the LED device undergoes light emission unevenness, and reduction in luminance occurs.

It is not easy to remove the irregularities of 500 nm or more formed through cleavage. In particular, the processing of the cleaved surface of the ScAlMgO₄ substrate encounters the following difficulty. In the case where the irregularities formed through cleavage are tried to be removed, when the proportion of the flat portion in the entire surface is large, the processing load tends to be concentrated to a partial area (irregularity) on processing the flat portion, and cracks occur due to cleavage in the deeper interior from the surface, but not on the surface. Accordingly, it is considered that irregularities are newly formed due to removal of the cracked portions. When the proportion of the flat portion is large, the application of a load that does not cause cleavage in the interior substantially cannot remove the irregularities formed in the cleaving step.

In view of the properties of the ScAlMgO₄ material, the processing method described in detail below (i.e., the coarse irregularity forming step and the minute irregularity forming step) has been found, and designated as the irregularity removing step of the embodiment. Specifically, an irregularity shape having a uniform height is formed over the entire surface of the region to be an epitaxial growth surface of the ScAlMgO₄ substrate (i.e., the coarse irregularity forming step). Subsequently, the irregularity shape having a uniform height having been formed on the entire surface is gradually reduced, while the pressing force is reduced stepwise to decrease the absolute value of the fluctuation of the pressing force, thereby preventing the cleavage in the interior (i.e., the minute irregularity forming step). More specifically, the ScAlMgO₄ single crystal is cleaved at the cleavage surface from the notch 2a as an origin to prepare the ScAlMgO₄ substrate 10 shown in the upper figure of FIG. 5(a). Subsequently, at least the coarse irregularity forming step of forming irregularities having a height of 500 nm on the principal surface of the ScAlMgO₄ substrate 10, and the minute irregularity forming step of forming irregularities having a height of less than 500 nm by polishing the irregularities having a height of 500 nm or more are performed.

In the coarse irregularity forming step, the irregularity shape is distributed over the entire surface of the region to be an epitaxial growth surface in such a manner that the areas of the regions each having continuously a height of the irregularities of 500 nm or less (which may be hereinafter referred to as a “flat portion”) are 1 mm² or less. This is because when the flat portion having an area exceeding 1 mm² is formed in the coarse irregularity forming step, the cleavage in the interior occurs in the minute irregularity forming step due to the processing load concentration, forming irregularities having a height exceeding 500 nm. The difference among the heights of the plural protruded parts of the irregularities formed in the coarse irregularity forming step is preferably within a range of ±0.5 μm. When the irregularities having a uniform height, which have the fluctuation in height within the range, are formed over the entire surface, the height of the irregularities can be gradually reduced in the minute irregularity forming step, and thereby a uniform flat portion can be formed on the surface.

Specifically, in the coarse irregularity forming step, irregularities having a height of 500 nm or more are formed with first abrasive grains, and in the minute irregularity forming step, irregularities having a height of less than 500 nm are formed with second abrasive grains having a hardness that is smaller than that of the first abrasive grains.

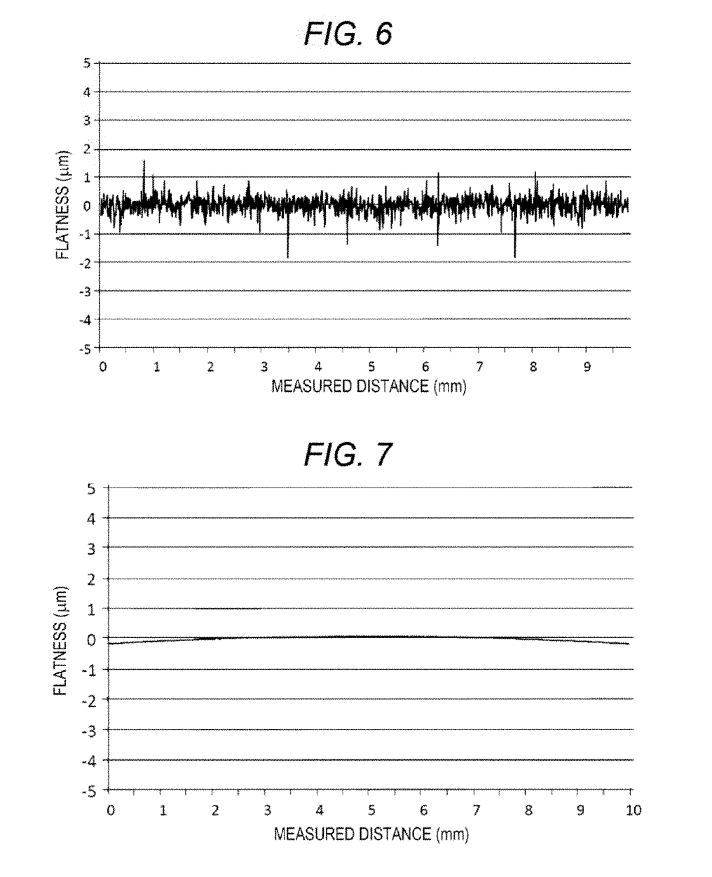

More specifically, in the irregularity forming step of processing an irregularity shape having a uniform height, a grinding process is performed with a diamond fixed whetstone having a large abrasive grain size. As for the abrasive grain size, diamond abrasive grains of #300 or more and #20000 or less (preferably #600) may be used. By the process using the diamond abrasive grains having a size within the range, the difference in height of the irregularities on the processed surface can be made within a range of ±5 μm. The processing conditions in the coarse irregularity forming step may be a rotation number of the whetstone of 500 min⁻¹ or more and 50,000 min⁻¹ or less (preferably 1,800 min ⁻¹) , a rotation number of the ScAlMgO₄ substrate of 10 min⁻¹ or more and 300 min⁻¹ or less (preferably 100 min⁻¹), a processing speed of 0.01 μm/sec or more and 1 μm/sec or less (preferably 0.3 μm/sec), and a processing elimination amount of 1 μm or more and 300 μm or less (preferably 20 μm). FIG. 6 shows the result after processing with a diamond whetstone of #600 under conditions of a rotation number of the whetstone of 1,800 min⁻¹, a rotation number of the ScAlMgO₄ substrate of 100 min⁻¹, a processing speed of 0.3 μm/sec, and a processing elimination amount of 20 μm. FIG. 6 shows the result obtained by measuring the flatness in the X direction of the processed surface in the same manner as described above. As shown in FIG. 6, on the region to be an epitaxial growth surface, 1 mm² or more of the flat portion (i.e., 1 mm² or more of the region having continuously a height of the irregularities of 500 nm or less) is not formed, and a well-regulated irregularity shape can be formed.

The minute irregularity forming step of gradually removing the irregularities formed in the coarse irregularity forming step will be then described. In the minute irregularity forming step, while the irregularities having a height of 500 nm are removed, irregularities having a height of less than 500 nm are formed by polishing with a pressing force that is reduced stepwise. In the minute irregularity forming step, a slurry containing colloidal silica as a major component is preferably used as abrasive grains, and polishing is preferably performed with a nonwoven cloth pad as a polishing pad at a rotation number of 10 min⁻¹ or more and 1,000 min⁻¹ or less (preferably 60 min⁻¹) and a slurry supplying amount of 0.02 mL/min or more and 2 mL/min or less (preferably 0.5 mL/min). The slurry supplying amount may be changed depending on the area of the substrate. Specifically, the slurry supplying amount is preferably increased when the area of the substrate is larger. In the case where a large amount of irregularities are formed, the processing force tends to be concentrated to the protruded parts thereof. Accordingly, the pressing force is preferably in a range of 10,000 Pa or more and 20,000 Pa or less in the initial stage of the minute irregularity forming step, then in a range of 5,000 Pa or more and less than 10,000 Pa when the protruded parts are being flattened, and finally in a range of 1,000 Pa or more and 5,000 Pa or less. By decreasing the pressing force stepwise in this manner, the irregularities having a height of 500 nm or more can be removed from the region to be an epitaxial growth surface while preventing the cleavage in the interior from occurring.

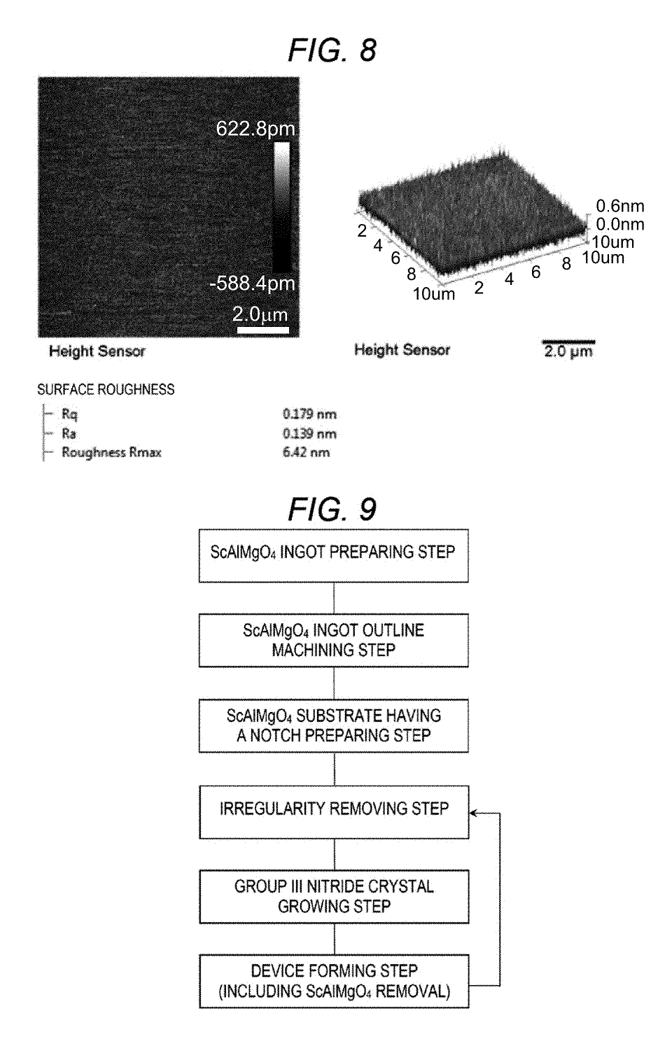

FIG. 7 shows the result obtained by performing polishing initially at a pressing force of 15,000 Pa for 3 minutes, then polishing at a pressing force reduced to 8,000 Pa for 5 minutes, and finally polishing at a pressing force reduced to 1,000 Pa for 10 minutes. FIG. 7 shows the result obtained by measuring the flatness in the X direction of the epitaxial growth surface after the processing, in the same manner as described above. FIG. 8 shows the measurement result of the surface shape measured with an AFM (atomic force microscope) for an area of 10 μm square on the epitaxial growth surface. As shown in FIG. 8, there is no irregularity having a height of 500 nm or more in the 10 μm square area, and no irregularity having a height of 50 nm or more is also not found, which is manifested by the maximum height Rmax of 6.42 nm. The value Rq is 0.179 nm. It is understood from FIG. 8, which is the result of the more detailed shape analysis, that in the minute area of 100 μm², the surface roughness Ra is 0.139 nm, and an extremely smooth surface having no irregularity of 50 nm or more can be formed. The surface roughness Ra of the epitaxial growth surface obtained herein is 0.08 nm or more and 0.5 nm or less. The surface roughness Ra is measured according to ISO 13565-1 with Dimension Icon, produced by Bruker Corporation. According to the procedures, the ScAlMgO₄ substrate 10 having an epi-ready surface is prepared.

The GaN crystal growing step will be then described. Examples of the method for growing a GaN single crystal include a vapor phase epitaxial growth method, in which Group V and Group III raw material gases are reacted with each other to synthesize the crystal, and a liquid phase epitaxial growth method using a solution or a molten liquid. Examples of the vapor phase epitaxial growth method used include an HVPE (hydride vapor phase epitaxial) method and an OVPE (oxide vapor phase epitaxial) method. Examples of the liquid phase epitaxial growth method include an Na flux (sodium flux) method.

The HVPE method uses GaCl as the Group III source. Specifically, metallic Ga and HCl gas are reacted to form GaCl gas in a raw material gas forming part of a quartz tube furnace. By increasing the reaction efficiency herein, substantially 100% of HCl is reacted to form GaCl gas. The GaCl gas is transported to a growth part having a seed substrate (ScAlMgO₄ substrate 10) disposed therein. The GaCl gas is then reacted with NH₃ gas at a temperature of approximately from 1,000 to 1,100° C. to form GaN. A characteristic feature of the HVPE method is that GaN can be grown at a high speed, and a GaN independent substrate of several hundred nanometers to several millimeters can be formed. In this embodiment, as shown in FIG. 5(b), a GaN layer 4 can be formed on the ScAlMgO₄ substrate 10.

As another method for forming the GaN layer 4, the OVPE method will be described. In the OVPE method, Ga₂O is used as a Ga source. In this method, Ga₂O gas is formed, and the Ga₂O gas and NH₃ gas are reacted with each other in the growing part to grow a GaN crystal. In this method, the by-products are only hydrogen and water vapor, which do not clog the exhaust system, and thus continuous growth for a prolonged period of time can be performed in principle.

In the case where the equipment for the HVPE method or the OVPE method is such an equipment that the gas is made to flow in the lateral direction, the ScAlMgO₄ substrate 10 is preferably disposed to make the notch 2b directed to the downstream side of the gas flow.

As still another method for forming the GaN layer 4, the Na flux method may be used. In the Na flux method, nitrogen is dissolved in a Ga-Na molten liquid at a high temperature to create a supersaturated state, in which GaN is grown. Specifically, a seed substrate (ScAlMgO₄ substrate 10), Ga, and Na are placed in a crucible, which is then placed in a stainless steel tube, and heated to a temperature of from 800 to 900° C. with a heater under application of a nitrogen pressure of from 3 to 4 MPa. Nitrogen is dissolved in the heated Ga-Na molten liquid, and thereby a GaN crystal is grown on the ScAlMgO₄ substrate 10. A characteristic feature of the Na flux method is that although the growing speed is lower than the HVPE method, the dislocation density is small, and a high quality GaN crystal with less defects can be obtained.

The ScAlMgO₄ removing step will be then described. In the case where a sapphire substrate is used as a seed substrate in an ordinary method having been practiced, the sapphire substrate and the GaN substrate are separated from each other in the temperature decreasing step of the GaN crystal growing process, due to the difference in expansion and contraction caused by the difference in thermal expansion of the sapphire substrate and the GaN layer. However, the thermal expansion coefficients of ScAlMgO₄ and GaN are close to each other, and in this embodiment, the ScAlMgO₄ substrate 10 and the GaN layer 4 are not separated from each other even after completion of the GaN crystal growth process. Accordingly, a separation process is necessarily performed.

The GaN layer 4 formed in the GaN crystal growing step has a distorted outer shape, and thus is processed to make the outer shape circular. For example, grinding with a rotating whetstone is performed. Subsequently, for removing the part of the ScAlMgO₄ substrate (corresponding to the part 10a in FIG. 5(b)), the blade 3 (i.e., the blade 3 shown in FIG. 3A or 3B) is attached to the notch 2b formed on the side portion of the ScAlMgO₄ substrate 10. A force is applied in the cleavage direction of the ScAlMgO₄ substrate 10 from the notch 2b as an origin, and thereby the ScAlMgO₄ substrate 10 is separated into an ScAlMgO₄ substrate 10b containing the GaN layer 4 and an ScAlMgO₄ substrate 10a. The ScAlMgO₄ substrate 10a thus separated can be regenerated as a seed crystal by the process described in the irregularity removing step.

The GaN substrate machining step will be then described. In this step, a Ga surface 20, which is the epitaxial growth surface of the GaN layer 4, and an N surface 21 having ScAlMgO₄ present thereon are ground and polished to finalize a GaN independent substrate 4a capable of growing epitaxially. The grinding may be performed by grinding with fixed abrasive grains or lapping with free abrasive grains. The polishing of the Ga surface 20 may be a method including lapping with small free abrasive grains and then removing a process affected layer, which is damaged crystals, by CMP (chemical mechanical polishing) . For the N surface 21, on the other hand, the ScAlMgO₄ substrate 10b is removed by grinding, and the N surface 21 is finished by polishing. According to the procedures, the GaN independent substrate 4a capable of growing epitaxially is formed as shown in FIG. 5 (d).

In this embodiment, the ScAlMgO₄ substrate 10a separated in the ScAlMgO₄ removing step is subjected again to the irregularity removing step, and thereby the ScAlMgO₄ substrate 10a can be used as a seed substrate. Accordingly, a GaN independent substrate can be formed by using again the regenerated ScAlMgO₄ substrate 10a. Therefore, ScAlMgO₄ can be efficiently used, and the material yield can be enhanced. The number of the notches 2b of the ScAlMgO₄ substrate 10 may not be necessarily one, and plural notches may be formed in the thickness direction of the substrate in the preparing step of an ScAlMgO₄ substrate having a notch, depending on the number of times of regeneration of the seed substrate.

### EMBODIMENT 2

FIG. 9 shows production process of a Group III nitride substrate according to the embodiment 2. The production process of the embodiment 2 contains: an ScAlMgO₄ ingot preparing step of forming a single crystal ScAlMgO₄; an ScAlMgO₄ ingot outline machining step of forming a cylindrical ingot from the single crystal ScAlMgO₄ and forming a notch on a side portion of the ingot; an ScAlMgO₄ substrate preparing step of machining the ingot into the form of a substrate to prepare an ScAlMgO₄ substrate having a notch; an irregularity removing step of removing irregularities on a surface corresponding to an epitaxial growth surface of the ScAlMgO₄ substrate; and a Group III nitride crystal growing step of epitaxially growing a Group III nitride crystal (for example, a GaN crystal) on the ScAlMgO₄ substrate; and a device forming step of forming a device. The device forming step contains ScAlMgO₄ removal of removing ScAlMgO₄ from the notch as an origin.

The difference from the embodiment 1 is that a Group III nitride crystal is epitaxially grown on the ScAlMgO₄ substrate, and furthermore the device is formed. The process steps until the irregularity removing step are the same as in the embodiment 1, and the Group III nitride crystal growing step and the latter will be described. However, in the irregularity removing step, the epitaxial growth surface may be formed only on one surface (front surface) of the ScAlMgO₄ substrate in the embodiment 1, whereas the epitaxial growth surfaces may be formed on both the surfaces of the ScAlMgO₄ substrate in the embodiment 2. In this case, epitaxial growth of a Group III nitride crystal (Group III nitride semiconductor), such as GaN, may be performed on both surfaces. For example, in the case where an LED light emitting layer is formed on the epitaxial growth surface of the substrate by utilizing the processing technique described above, the problems including the change of the composition, and light emission unevenness and reduction in luminance of the LED device caused thereby may not occur. Furthermore, the height of the irregularities on the epitaxial growth surface of the ScAlMgO₄ substrate is reduced to 50 nm or less by the irregularity removing step, and thereby for example, in the case of forming an electrode after forming the LED light emitting layer on the epitaxial growth surface, the formation failure thereof (such as an etching residue at steps) due to the irregularities can be suppressed. Accordingly, the production yield of the device, such as an LED, using the substrate can be enhanced.

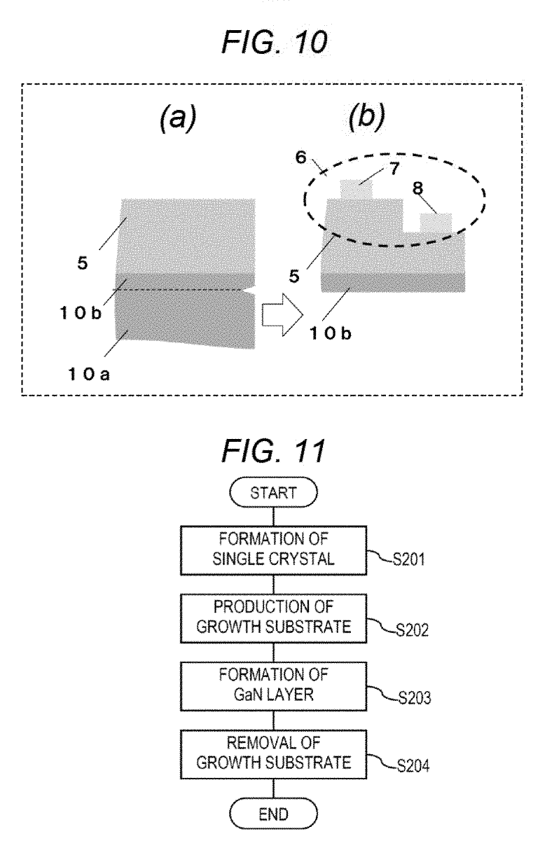

In the crystal growing step in the embodiment 2, vapor phase epitaxial growth of a Group III nitride is performed on the epitaxial growth surface of the ScAlMgO₄ substrate 10, for example, by an MOCVD method, to grow the Group III nitride crystal layer 5 shown in FIG. 10(a). When the vapor phase epitaxial growth of a Group III nitride is performed on the ScAlMgO₄ substrate, for example, by an MOCVD method, the raw material of the Group III nitride migrates on the (0001) plane as the cleavage surface of the epitaxial growth surface, and stops at a stable position if any and is epitaxially grown.

In the Group III nitride crystal layer forming step, for example, a Group III nitride crystal layer 5 containing a laminated material of an n-type nitride semiconductor layer, an active layer, and a p-type nitride semiconductor layer (which is a light emitting layer of an LED device) can be formed. The n-type nitride semiconductor layer used may be a layer formed of an n-type AlᵤGaᵥIn_{w}N (wherein u+v+w=1, u≧0, v≧0, and w≧0). The n-type dopant used may be silicon (Si). The n-type dopant used may also be oxygen (O) or the like in addition to Si. The active layer may be a layer (well layer) having an MQW (multiple quantum well) structure formed of GaInN/GaN containing Ga₁₋ₓInₓN (wherein 0<x<1) well layers each having a thickness of approximately from 3 to 20 nm and GaN barrier layers each having a thickness of approximately from 5 to 30 nm, which are laminated alternately. The wavelength of the light that is emitted by the LED device is determined by the extent of the band gap of the nitride semiconductor constituting the active layer, and specifically determined by the composition x of In in the Ga₁₋ₓInₓN semiconductor as the semiconductor composition of the well layer. The p-type nitride semiconductor layer may be, for example, a layer formed of a p-type AlₛGaₜN (wherein s+t=1, s≧0, and t≧0) semiconductor. The p-type dopant used may be magnesium (Mg). The p-type dopant used may also be zinc (Zn), beryllium (Be), or the like in addition to Mg.

The device forming step will be then described. In the device forming step, the Group III nitride crystal layer 5 laminated in the Group III nitride crystal growing step is processed into a desired shape, for example, by a lithography method, a dry etching method, or the like. For example, a concave portion 6 is formed by removing a part of the p-type nitride semiconductor layer, the active layer, and the n-type nitride semiconductor layer, thereby forming an electrode. Subsequently, an n-electrode 8 that is electrically connected to the n-type nitride semiconductor layer and a p-electrode 7 that is electrically connected to the p-type nitride semiconductor layer are formed. The n-electrode 8 may be formed, for example, of a laminated structure (Ti/Pt) containing a titanium (Ti) layer and a platinum (Pt) layer, or the like. In addition, a laminated structure (Ti/Al) containing a titanium (Ti) layer and an aluminum (Al) layer may also be used. The p-electrode 7 may be formed, for example, of a laminated structure (Pd/Pt) containing a palladium (Pd) layer and a platinum (Pt) layer, or the like. In addition, a silver (Ag) layer may also be used.

The ScAlMgO₄ 10a formed on the side of the Group III nitride crystal layer 5 opposite to the crystal growth surface is then removed. Specifically, a blade is attached to the notch 2b formed on the side portion of the ScAlMgO₄ substrate 10, and a force is applied in the cleavage direction of the ScAlMgO₄ substrate 10, thereby separating the ScAlMgO₄ substrate 10 into the ScAlMgO₄ substrate 10b containing the device structure formed of the Group III nitride crystal layer 5, the electrodes, and the like shown in FIG. 10 (b) , and the ScAlMgO₄ substrate 10a. The ScAlMgO₄ substrate 10a thus separated can be regenerated as a seed crystal by the irregularity removing step described for the embodiment 1. Accordingly, in this embodiment, ScAlMgO₄ can be efficiently used, and the material yield can be enhanced. The number of the notches 2b of the ScAlMgO₄ substrate 10 may not be necessarily one, and plural notches may be formed in the thickness direction of the substrate in the preparing step of an ScAlMgO₄ substrate 10 having a notch, depending on the number of times of regeneration of the ScAlMgO₄ substrate 10. Specifically, by forming plural notches in the ScAlMgO₄ substrate preparing step, the ScAlMgO₄ substrate 10 can be used multiple times. In the regeneration of the ScAlMgO₄ substrate 10a, the ScAlMgO₄ substrate 10a is polished to have a prescribed thickness. Furthermore, a minute irregularity structure may be formed in the minute irregularity forming step in the irregularity removing step, and thereby the light extraction efficiency can be enhanced.

### OTHERS

While the embodiments 1 and 2 describe the substrate obtained from a ScAlMgO₄ single crystal as a substrate formed of a single crystal represented by the general formula RAMO₄, the embodiments are not limited thereto. Specifically, the substrate represented by the ScAlMgO₄ substrate of the embodiments is constituted by a substantially sole crystal material represented by the general formula RAMO₄. In the general formula, R represents one or a plurality of trivalent elements selected from Sc, In, Y, and a lanthanoid element (atomic number: 67 to 71) , A represents one or a plurality of trivalent elements selected from Fe (III) , Ga, and Al, and M represents one or a plurality of divalent elements selected from Mg, Mn, Fe (II), Co, Cu, Zn, and Cd. The substantially sole crystal material means a crystalline solid, in which the material contains 90% by atom or more of the RAMgO₄ constituting the epitaxial growth surface, and in terms of an arbitrary crystal axis, the direction of the crystal axis is not changed in any part on the epitaxial growth surface. However, a material having a crystal axis that is locally changed in direction thereof and a material containing local lattice defects are handled as a single crystal. O represents oxygen. As described above, it is particularly preferred that R is Sc, A is Al, and M is Mg.

The Group III nitride crystal grown on the substrate formed of the single crystal is also not limited to GaN, an n-type nitride semiconductor layer, an active layer, a p-type nitride semiconductor layer, and the like. While the Group III metal element constituting the Group III nitride is most preferably gallium (Ga), examples of the Group III metal element also include aluminum (Al), indium (In), and thallium (Tl), and the Group III nitride may contain only one kind of the Group III metal element or two or more kinds thereof in combination. For example, at least one selected from the group consisting of aluminum (Al), gallium (Ga), and indium (In) may be used as the Group III metal element. In this case, the composition of the Group III nitride crystal thus produced is represented by AlₛGaₜIn₍₁₋₍ₛ₊ₜ₎₎N (wherein 0≦s≦1, 0≦t≦1, and s+t≦1), and in the embodiment 1, GaN is preferably used as the Group III nitride. Examples of the ternary or higher nitride crystal produced with two or more kinds of the Group III metal elements include a crystal of GaₓIn₁₋ₓN (wherein 0<x1) .

In the production of an LED device by growing an LED light emitting layer on a substrate by MOCVD vapor phase epitaxial growth, the use of the substrate of the embodiments can prevent light emission unevenness and reduction in luminance of the LED device, while enhancing the material efficiency of the material for the seed substrate.

What is claimed is:

1. A method for producing a Group III nitride crystal, comprising: preparing a RAMO₄ substrate containing a single crystal represented by the general formula RAMO₄ (wherein R represents one or a plurality of trivalent elements selected from a group consisting of Sc, In, Y, and a lanthanoid element, A represents one or a plurality of trivalent elements selected from a group consisting of Fe(III), Ga, and Al, and M represents one or a plurality of divalent elements selected from a group consisting of Mg, Mn, Fe(II), Co, Cu, Zn, and Cd) having a notch on a side portion of the RAMO₄ substrate;
growing a Group III nitride crystal on the RAMO₄ substrate; and
cleaving the RAMO₄ substrate from the notch.

2. The method for producing a Group III nitride crystal according to claim 1, wherein the method further comprises: reusing the RAMO₄ substrate cleaved from the notch, and newly growing a Group III nitride crystal on the cleaved RAMO₄ substrate.

3. The method for producing a Group III nitride crystal according to claim 1, wherein the notch is one of a plurality of notches being provided in a thickness direction of the RAMO₄ substrate.

4. The method for producing a Group III nitride crystal according to claim 1, wherein the RAMO₄ substrate is an ScAlMgO₄ substrate.

5. The method for producing a Group III nitride crystal according to claim 1, wherein the Group III nitride crystal is GaN.

6. An RAMO₄ substrate comprising a single crystal represented by the general formula RAMO₄ (wherein R represents one or a plurality of trivalent elements selected from a group consisting of Sc, In, Y, and a lanthanoid element, A represents one or a plurality of trivalent elements selected from a group consisting of Fe(III), Ga, and Al, and M represents one or a plurality of divalent elements selected from a group consisting of Mg, Mn, Fe(II), Co, Cu, Zn, and Cd),
the RAMO₄ substrate having a notch on a side portion thereof.

7. The RAMO₄ substrate according to claim 6, wherein the notch is one of a plurality of notches being provided in a thickness direction of the RAMO₄ substrate.

8. The RAMO₄ substrate according to claim 6, wherein the substrate further comprises a Group III nitride crystal on a surface thereof.

9. The RAMO₄ substrate according to claim 6, wherein the single crystal is ScAlMgO₄.

10. The RAMO₄ substrate according to claim 6, wherein the substrate further comprises GaN on a surface thereof.

11. The RAMO₄ substrate according to claim 6, wherein the notch has a depth of at least 0.1 mm and no greater than 5 mm and a width in a circumferential direction of at least 0.1 mm and no greater than 15 mm.
